(19) United States
(12) Patent Application Publication
(10) Pub. No.: US 2025/0192392 A1
(43) Pub. Date: Jun. 12, 2025

(54) BATTERY CELL WITH INTEGRATED VOLTAGE SENSE ELEMENT

(71) Applicant: GM Global Technology Operations LLC, Detroit, MI (US)

(72) Inventors: Andrew P. Oury, Troy, MI (US); Andrew Geoffrey Balding, Wixom, MI (US); Seung-Woo Chu, Sterling Heights, MI (US)

(21) Appl. No.: 18/533,450

(22) Filed: Dec. 8, 2023

(51) Int. Cl. H01M 50/569; H01M 10/48; H01M 50/105; H01M 50/119; H01M 50/178; H01M 50/548

(52) U.S. Cl. CPC H01M 50/569; H01M 10/48; H01M 50/105; H01M 50/119; H01M 50/178; H01M 50/548; H01M 2220/20

(57) ABSTRACT

A battery includes a plurality of cells arranged in a stack. The cells include a first set of cells and every cell in the first set of cells includes an internal energy storage element disposed within a sealed pouch. The internal energy storage element includes an anode terminal extending through the pouch from a first end of the internal power storage element and a cathode terminal extending through the pouch from a second end of the internal power storage element with the second end being opposite the first end. A conductive element connects the cathode terminal to a sensor terminal on the first end. The conductive element passes internal to at least an outermost layer of the sealed pouch.

### INTRODUCTION

The subject disclosure relates to a battery cell, and more particularly to a battery cell including an integrated voltage sense element.

Rechargeable energy storage systems (RESS) typically include one or more battery packs having rechargeable energy storage cells. The battery pack is connectable to an external charging system that replenishes electrical energy lost to a load. The charging system may be part of a vehicle or may be part of an external charging station. When providing power to a vehicle, the battery pack discharges stored electrical energy.

Monitoring a state of charge of the RESS typically includes monitoring the state of charge of each cell by measuring a voltage at a cathode terminal and anode terminal of each cell. Due to packaging and thermal requirements, the cells within a given stack are not always aligned such that the cathode terminal and anode terminal are on the same side of the stack, and the corresponding circuitry required to connect the voltage sensor to each cathode terminal and anode terminal is complex and contacts the stack at multiple locations.

Accordingly, it is desirable to provide a cell and stack configuration that allows for a minimized complexity and contact between the sensor and the stack.

### SUMMARY

In one exemplary embodiment a battery includes a plurality of cells arranged in a stack. The cells include a first set of cells and every cell in the first set of cells includes an internal energy storage element disposed within a sealed pouch. The internal energy storage element includes an anode terminal extending through the pouch from a first end of the internal energy storage element and a cathode terminal extending through the pouch from a second end of the internal energy storage element with the second end being opposite the first end. A conductive element connects the cathode terminal to a sensor terminal on the first end. The conductive element passes internal to at least an outermost layer of the sealed pouch.

In addition to one or more of the features described herein the conductive element is a wire connecting the cathode terminal to the sensor terminal.

In addition to one or more of the features described herein the wire is connected to the cathode terminal at a cathode tab pouch overlap region.

In addition to one or more of the features described herein the conductive element is a metallic layer of the sealed pouch, and wherein the pouch is pierced at the second end such that the metallic layer contacts the cathode terminal.

In addition to one or more of the features described herein the pouch is pierced at the first end such that the metallic layer contacts the sensor terminal at the first end.

In addition to one or more of the features described herein the pouch is pierced via a pin having a spiral feature at a piercing end.

In addition to one or more of the features described herein the spiral feature is one of a threading extending from a shaft at the piercing end, a set of dimple intrusions arranged in spiral about the shaft at the piercing end, and a set of pin shaped protrusions arranged in a spiral about the shaft at the piercing end.

In addition to one or more of the features described herein the sealed pouch comprises a multi-layer foil having at least an inner layer, a metallic layer exterior to the inner layer, and an outer layer exterior to the metallic layer.

In addition to one or more of the features described herein the metallic layer is an aluminum alloy.

In addition to one or more of the features described herein the plurality of cells arranged in the stack further includes a second set of cells, and wherein the second set of cells omit the conductive element connecting the cathode terminal to the sensor terminal.

In addition to one or more of the features described herein the stack comprises alternating groups of cells from the first set of cells and the second set of cells, and wherein an anode tab of each cell is aligned with an anode tab of each other cell in the stack.

In another exemplary embodiment a vehicle includes a battery system electrically coupled to at least a first electric motor, the battery system including a state of charge sensor configured to monitor a state of charge of at least one battery, and wherein the battery includes a plurality of cells arranged in a stack. The plurality of cells include a first set of cells. Every cell in the first set of cells includes an internal energy storage element disposed within a sealed pouch. The internal energy storage element includes an anode terminal extending through the pouch from a first end of the internal energy storage element and a cathode terminal extending through the pouch from a second end of the internal energy storage element. The second end is opposite the first end. A conductive element connects the cathode terminal to a sensor terminal on the first end. The conductive element passes internal to at least an outermost layer of the sealed pouch.

In addition to one or more of the features described herein the conductive element is a wire connecting the cathode terminal to the sensor terminal.

In addition to one or more of the features described herein the wire is connected to the cathode terminal at a cathode tab pouch overlap region.

In addition to one or more of the features described herein the conductive element is a metallic layer of the sealed pouch, and wherein the pouch is pierced at the second end such that the metallic layer contacts the cathode terminal.

In addition to one or more of the features described herein the pouch is pierced at the first end such that the metallic layer contacts the sensor terminal at the first end.

In addition to one or more of the features described herein the pouch is pierced via a pin having a spiral feature at a piercing end.

In addition to one or more of the features described herein the sealed pouch comprises a multi-layer foil having at least an inner layer, a metallic layer exterior to the inner layer, and an outer layer exterior to the metallic layer.

In addition to one or more of the features described herein the metallic layer is an aluminum alloy.

In addition to one or more of the features described herein the plurality of cells arranged in the stack further includes a second set of cells, and wherein the second set of cells omit the conductive element connecting the cathode terminal to the sensor terminal.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is an exemplary vehicle;

FIG. 2 illustrates a stack of n cells, forming a single battery pack;

FIG. 3 is a schematic view of a first example cell which can be included in the stack of FIG. 2;

FIG. 4A is a perspective view of the example cell of FIG. 2 according to one example;

FIG. 4B is a partial sectional view of FIG. 4A taken at cross section A- A.

FIG. 5A is a first example of a piercing element;

FIG. 5B is a second example of a piercing element; and

FIG. 5C is a third example of a piercing element.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. As used herein the term controller refers to any computerized control system including dedicated control systems, general vehicle controllers, control programs distributed across multiple systems, or any similar control architecture.

In accordance with an exemplary embodiment, a battery stack for a rechargeable battery includes multiple cells stacked to cumulatively provide an output power from internal energy storage elements within each cell, with the internal energy storage elements being surrounded by a pouch. Each cell includes an anode tab extending from one side of the cell and a cathode tab extending from the opposite side of the cell, with the anode tab providing a negative output terminal and the cathode tab providing a positive output terminal. In order to monitor the cell voltages, a sensor identifies the voltage at each cathode and anode tab. To facilitate the sensor monitoring at least a portion of the cells include a conductive element connecting the cathode tab to a separate sensor terminal on the same side as the anode tab. The conductive element is integral to the cell and contained interior to at least an outermost layer of the pouch.

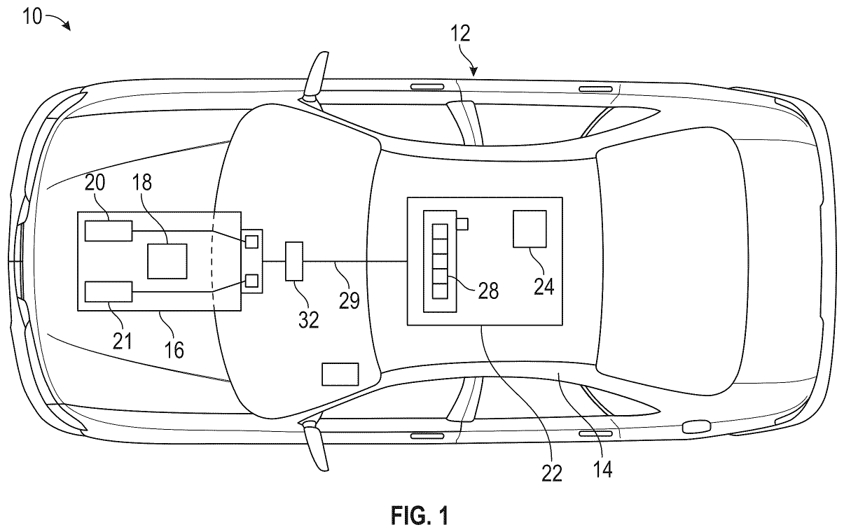

With continued reference to the general system described above, FIG. 1 shows an embodiment of a motor vehicle 10. The vehicle 10 includes a vehicle body 12 defining, at least in part, an occupant compartment 14. The vehicle body 12 also supports various vehicle subsystems including a propulsion system 16, a battery system 22, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine system 18 and at least one electric motor assembly. For example, the propulsion system 16 includes a first electric motor 20 and a second electric motor 21. The motors 20 and 21 may be configured to drive wheels on opposing sides of the vehicle 10. Any number of motors positioned at various additional locations about the vehicle 10 may be used to provide power to corresponding systems and subsystems.

The battery system 22 may be electrically connected to the motors 20 and 21 and/or other components, such as vehicle electronics. The battery system 22 may be configured as a rechargeable energy storage system (RESS) and includes multiple power cells partitioned into portions. A battery system controller 24 is included within the battery system 22 and controls the charging and discharging functions of the batteries within the battery system 22. In alternative configurations, the battery system controller 24 can be a general vehicle controller remote from the battery system 22 and configured to control multiple systems and/or subsystems. The general vehicle controller can be located at any position within the vehicle 10. In yet further alternatives, the battery system controller 24 can be a distributed control system including multiple coordinating controllers throughout the vehicle 10 encompassing controllers within the battery system 22 and controllers remote from the battery system 22.

In one embodiment, the battery system 22 includes multiple battery packs 28. The battery packs 28 include multiple distinct battery power cells (cells) arranged in parallel and in series and connected to a power distribution bus 29 for providing power to one or more systems. In the exemplary system of FIG. 1, the power distribution bus 29 is illustrated in simplified form as a single line and provides power to the propulsion systems 16 through an inverter 32.

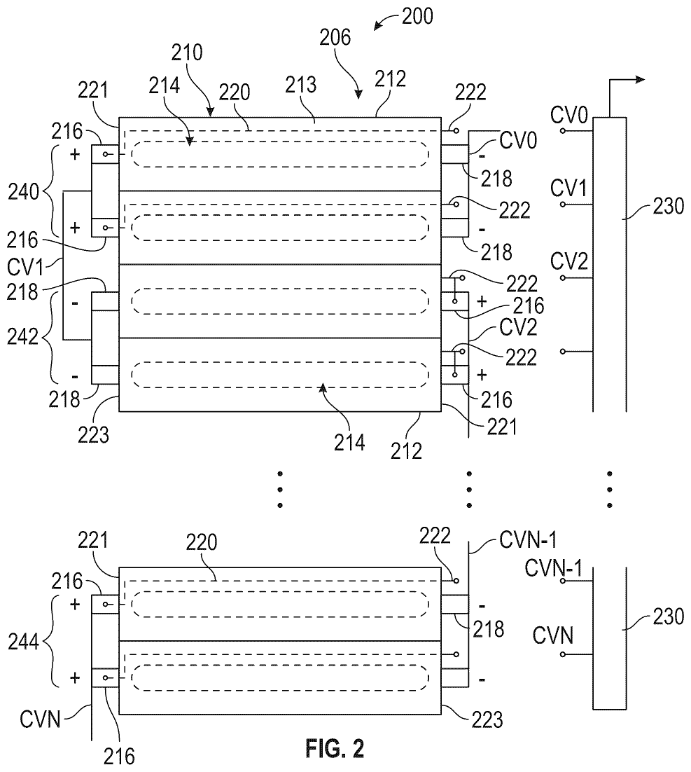

With continued reference to FIG. 1, FIG. 2 schematically illustrates a stack 206 of n cells 210, forming a single battery pack 200. Each cell 210, includes a pouch 212 housing internal energy storage elements 214. The internal energy storage elements 214 can, in one example, include anode and cathode layers disposed within an electrolyte fluid or solid electrolyte system. A cathode tab 216 extends outward from a first end of the internal energy storage elements 214 and through the pouch 212 to provide a positive power terminal. Similarly, an anode tab 218 extends from a second end of the internal energy storage elements 214 and through the pouch 212 to provide a negative power output terminal.

In the illustrated stack 206, the cells 210 are oriented in a repeating pattern of two cells 210 oriented in a first direction, followed by two cells 210 in a second direction, then two cells 210 in the first direction, etc. Each pair of two cells 210 defines a cell group 240, 242, 244. Each pair of cells 210 in a given cell group 240, 242, 244 is connected in parallel. Each cell group 240, 242, 244 is connected in series to the next cell group 240, 242, 244 at a series connection CV0, CV1, CV2 . . . CVN-1, CVN. Each series connection CV0, CV1, CV2 . . . CVN-1, CVN has a voltage, and the voltage of a cell group 240, 242, 244 is a voltage of a first series connection CV0, CV1, CV2 . . . CVN-1, CVN connected to the cell group 240, 242, 244 minus a voltage of a second series connection CV9, CV1, CV2 . . . CVN-1, CVN connected to the cell group 240, 242, 244. By way of example, the voltage of cell group 240 is CV1 minus CV0. The values are identified using cell voltage monitors.

Typical cell voltage monitors retrieve the voltage at the cathode tab 216 and anode tab 218 of each cell 210. When cell groups 240, 242, 244 are connected in series, the cathode tab 216 of one cell group 240, 242, 244 is connected to the anode tab 218 of the next cell group 240, 242, 244, making their voltage equivalent. When the cells 210 are configured in alternating orientations in the cell stack 206, the circuitry needed to connect a sensor 230 to the terminals is complex and heavy and can result in degradation of the cells 210 at locations where the sensor 230 framework contacts the cells 210.

In order to reduce the complexity of the sensor connections, half of the cells 210 in the stack of FIG. 2 include a conductive element 220 connecting the cathode tab 216, distal to the sensor 230, to a sensor terminal 222 on the end of the cell 210 with the anode tab 218, proximal to the sensor 230. The sensor terminal 222 allows the circuitry for the sensor 230 to connect to, and read, a cathode tab 216 voltage of all of the cells 210 at a single side of the cell stack 206, thereby reducing complexity and reducing contact points. The conductive element 220 is positioned internal to at least the outermost layer of the pouch 212.

In some examples the conductive element 220 is a lead wire that extends through an interior portion 213 of the pouch 212. In other examples the conductive element 220 is one or more conductive layers of the material from which the pouch 212 is made with a puncture or weld in the pouch 212 connecting the one or more conductive layers to the cathode tab 216 at an end 221 of the pouch 212 and a second puncture or weld in the pouch 212 connecting the one or more conductive layers of the pouch 212 to the sensor terminal 222 on the end 223 of the pouch 212 through which the anode 218 extends. In the cells 210 lacking the conductive element 220, the sensor terminal 222 is connected directly to the cathode tab 216.

Each of the sensor terminals 222 is connected to a sensor 230, which provides the sensed values to the battery system controller 24 which utilizes the sensed values in any conventional manner.

While FIG. 2 illustrates a stack 206 including cells 210 alternating between a first orientation and a second orientation in a pattern where every two cells 210 alternate orientations, it is appreciated that alternating orientation every other cell 210, every three cells 210, or any similar alternating configuration can be utilized depending on the particular needs of a given battery and/or stack 206. In some particular examples, the alternating pattern used is driven by packaging constraints. In other examples, the alternating pattern is driven by thermal considerations. In yet other examples, the alternating pattern is drive by a combination of packaging and thermal constraints.

Similarly, while the stack 206 illustrated in FIG. 2 includes a first cell group 240 having the conductive element 220 and a second cell group 242 omitting the conductive element 220 due to the first and second orientations, it is appreciated that all cells 210 in both the first and second orientations can include the conductive element 220, and the sensor 230 can connect to the cathode tabs 216 of the cells 210 in the first orientation and the sensor terminals 222 of the cells 210 in the second orientation.

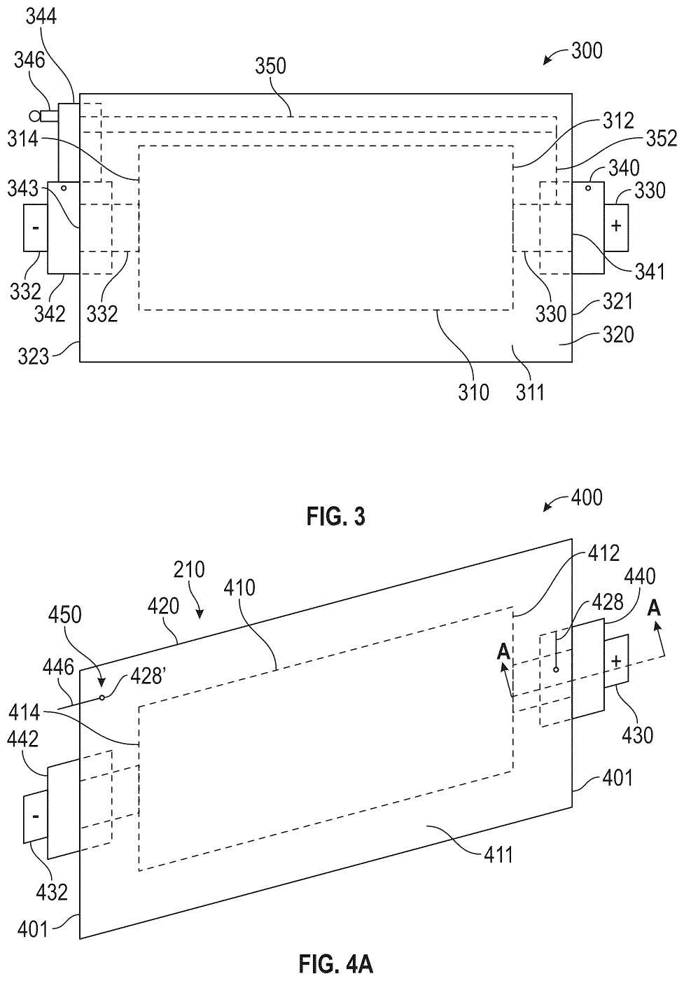

With continuing reference to FIG. 2, FIG. 3 schematically illustrates, in more detail, a first example cell 300 which can be included in a stack, such as the stack 206 of FIG. 2. The cell 300 includes an energy storage element 310 disposed within a sealed pouch 320, with an electrolyte fluid or solid electrolyte system 311 surrounding the energy storage element 310. A cathode tab 330 extends from a first end 312 of the energy storage element 310 through the pouch 320 defining a cathode terminal at a first end 321. An anode tab 332 extends from a second end 314 of the inner energy storage element 310 and through a second end 323 of the pouch 320 and defines an anode terminal. The second end 314 of the pouch 320 is opposite the first end 312, such that the anode tab 332 and cathode tab 330 are on opposite ends of the energy storage element 310 and the pouch 320.

A lead tab film 340 is disposed around the cathode tab 330 at a position 341 where the pouch 320 is sealed around the cathode tab 330, and electrically isolates the cathode tab 330 from the pouch 320. Similarly, a second lead film tab 342 is at a position 343 where the pouch 320 is sealed around the anode tab 332. In the illustrated example, the second lead film tab 342 includes an extension portion 344. The extension portion 344 extends to encompass a sensor terminal 346.

The sensor terminal 346 is attached to a conductive element 350 (e.g. a wire, foil, or a bar). The conductive element 350 is connected to the cathode tab 330 via a connection 352 positioned within the first lead film tab 340.

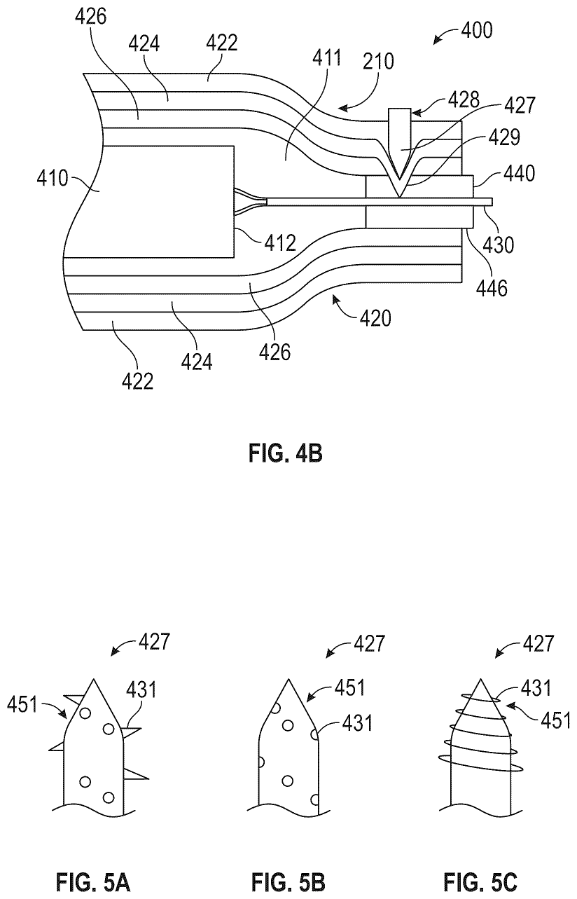

With continued reference to FIGS. 1 and 2, FIGS. 4A and 4B illustrate an alternate example cell construction 400 that can be used for the cells 210 of the stack 206 illustrated in FIG. 2. FIG. 4A is a schematic view of the cell 210. FIG. 4B is a partial schematic view of the cell 210 at cross section A-A. As with the example of FIG. 3, the cell 210 includes an energy storage element 410 disposed within a pouch 420. Cathode tab 430 and an anode tab 432 extend from opposite ends 412, 414 of the energy storage element 410. Each of the cathode tab 430 and the anode tab 432 extend through the sealed edges 401 of the pouch 420 through a corresponding lead film tab 440, 442. Each lead film tab 440, 442 surrounds the corresponding cathode tab 430 or anode tab 432, isolating the cathode tab 430 or anode tab 432 from the pouch 420.

In the example of FIGS. 4A and 4B, the pouch 420 is constructed of at least three layers 422, 424, 426 of material. The innermost layer(s) 426 and the outermost layer(s) 422 are non-conductive materials, and the middle layer 424 is constructed of a conductive material, such as a metallic foil. In one example, the metallic foil is an aluminum alloy. Instead of providing a conductive element in the electrolyte space 411 inside the pouch 420, the construction of FIGS. 4A and 4B utilizes the conductive middle layer 424 as the conductive element. While illustrated in FIG. 4A and 4B as utilizing three layers, alternative pouch constructions including more than three layers can be utilized in a similar manner, provided the inner layer 426 and the outer layer 422 are non-conductive, and at least one middle layer 424 is conductive.

To electrically connect the middle layer 424 to the cathode tab 430, the inner layer 426 and the outer layer 422 are pierced, with a piercing implement 428, FIG. 4B, pushing the middle layer 424 into contact with the cathode tab 430 at a contact point 429. In order to maintain the middle layer 424 in contact with the cathode tab 430, the piercing implement is maintained in the pouch. As illustrated, the middle layer 424 pierces the lead film tab 440 as well.

The piercing element 428 can be, in some examples, a laser weld or ultrasonic weld. In alternative examples, the piercing implement 428 can be a pin 427 forcibly driven through the layers 422, 424, 426, with the pin including features configured to force the middle layer 424 into contact with the cathode tab 430. Features of a pin 427 are illustrated in FIGS. 5A, 5B and 5C.

At the second end 401, the pouch 420 is pierced at a second location 450 via a second piercing implement 428′. The second piercing implement 428′ is electrically connected to the sensor terminal 446 and does not overlap the corresponding lead film tab 442. In some examples the second piercing implement 428′ is structurally the same as the first piercing implement 428.

With continued reference to FIGS. 4A and 4B above, FIGS. 5A, 5B and 5C illustrate partial views of exemplary pins 427, each with a distinct piercing feature 431 disposed at an end 451 thereof. In FIG. 5A the piercing features 431 are pins 427 extending outwardly from the piercing implement 428, with the pins being smaller than the piercing implement 428. In FIG. 5B, the piercing features 431 are divots (intrusions into the pin 427) disposed in a spiral thereabout. In FIG. 5C, the spiral feature 431 is threading.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A battery comprising:
a plurality of cells arranged in a stack, the plurality of cells including a first set of cells;
every cell in the first set of cells including:
an internal energy storage element disposed within a sealed pouch, the internal energy storage element including an anode terminal extending through the pouch from a first end of the internal energy storage element and a cathode terminal extending through the pouch from a second end of the internal energy storage element, the second end being opposite the first end, a conductive element connecting the cathode terminal to a sensor terminal on the first end, wherein the conductive element passes internal to at least an outermost layer of the sealed pouch.

2. The battery of claim 1, wherein the conductive element is a wire connecting the cathode terminal to the sensor terminal.

3. The battery of claim 2, wherein the wire is connected to the cathode terminal at a cathode tab pouch overlap region.

4. The battery of claim 1, wherein the conductive element is a metallic layer of the sealed pouch, and wherein the pouch is pierced at the second end such that the metallic layer contacts the cathode terminal.

5. The battery of claim 4, wherein the pouch is pierced at the first end such that the metallic layer contacts the sensor terminal at the first end.

6. The battery of claim 5, wherein the pouch is pierced via a pin having a piercing feature at a piercing end, wherein the piercing feature is disposed about the piercing end in a spiral.

7. The battery of claim 6, wherein the piercing feature is one of a threading extending from a shaft at the piercing end, a set of dimple intrusions arranged in spiral about the shaft at the piercing end, and a set of pin shaped protrusions arranged in a spiral about the shaft at the piercing end.

8. The battery of claim 4, wherein the sealed pouch comprises a multi-layer foil having at least an inner layer, a metallic layer exterior to the inner layer, and an outer layer exterior to the metallic layer.

9. The battery of claim 6, wherein the metallic layer is an aluminum alloy.

10. The battery of claim 1, wherein the plurality of cells arranged in the stack further includes a second set of cells, and wherein the second set of cells omit the conductive element connecting the cathode terminal to the sensor terminal.

11. The battery of claim 10 wherein the stack comprises alternating groups of cells from the first set of cells and the second set of cells, and wherein an anode tab of each cell is aligned with an anode tab of each other cell in the stack.

12. A vehicle comprising:
a battery system electrically coupled to at least a first electric motor, the battery system including a state of charge sensor configured to monitor a state of charge of at least one battery, and wherein the battery comprises:
a plurality of cells arranged in a stack, the plurality of cells including a first set of cells, and every cell in the first set of cells includes:
an internal energy storage element disposed within a sealed pouch, the internal energy storage element including an anode terminal extending through the pouch from a first end of the internal energy storage element and a cathode terminal extending through the pouch from a second end of the internal energy storage element, the second end being opposite the first end; and
a conductive element connecting the cathode terminal to a sensor terminal on the first end, wherein the conductive element passes internal to at least an outermost layer of the sealed pouch.

13. The battery of claim 12, wherein the conductive element is a wire connecting the cathode terminal to the sensor terminal.

14. The battery of claim 13, wherein the wire is connected to the cathode terminal at a cathode tab pouch overlap region.

15. The battery of claim 12, wherein the conductive element is a metallic layer of the sealed pouch, and wherein the pouch is pierced at the second end such that the metallic layer contacts the cathode terminal.

16. The battery of claim 15, wherein the pouch is pierced at the first end such that the metallic layer contacts the sensor terminal at the first end.

17. The battery of claim 16, wherein the pouch is pierced via a pin having a piercing feature at a piercing end, wherein the piercing feature is disposed about the piercing end in a spiral.

18. The battery of claim 15, wherein the sealed pouch comprises a multi-layer foil having at least an inner layer, a metallic layer exterior to the inner layer, and an outer layer exterior to the metallic layer.

19. The battery of claim 18, wherein the metallic layer is an aluminum alloy.

20. The battery of claim 12, wherein the plurality of cells arranged in the stack further includes a second set of cells, and wherein the second set of cells omit the conductive element connecting the cathode terminal to the sensor terminal.
